(19) United States
(12) Patent Application Publication
(10) Pub. No.: US 2016/0261255 A1
(43) Pub. Date: Sep. 8, 2016

(54) ACCURATELY DETECTING LOW CURRENT THRESHOLD

(71) Applicant: LINEAR TECHNOLOGY CORPORATION, Milpitas, CA (US)

(72) Inventors: Andrew Joseph Gardner, Santa Barbara, CA (US); David McLean Dwelley, Santa Barbara, CA (US)

(73) Assignee: LINEAR TECHNOLOGY CORPORATION, Milpitas, CA (US)

(21) Appl. No.: 15/061,715

(22) Filed: Mar. 4, 2016

Related U.S. Application Data
(60) Provisional application No. 62/128,877, filed on Mar. 5, 2015.

(51) Int. Cl. H03K 5/153; H03K 5/24

(52) U.S. Cl. CPC H03K 5/153; H03K 5/24

(57) ABSTRACT

A threshold detection circuit may sense when current between a power supply and a load reaches a current threshold level. The threshold detection circuit may include a transistor in series with the load; a feedback circuit that causes the voltage drop across the transistor to be constant while the transistor is conducting current between the power supply and the load; a constant current source that delivers a constant current into the load; and a comparator that indicates when the voltage drop across the transistor falls below a voltage threshold level.

### CROSS-REFERENCE TO RELATED APPLICATION

This application is based upon and claims priority to U.S. provisional patent application No. 62/128,877, entitled “Scheme for Detecting a Disabled or Disconnected PD while Power is Applied for Power over Data Lines Systems,” filed Mar. 5, 2015. The entire content of this application is incorporated herein by reference.

### BACKGROUND

1. Technical Field

This disclosure relates to sensing current between a power supply and a load, and providing an accurate indication when a very low current threshold level is reached.

2. Description of Related Art

It can be useful to sense when current between a power supply and a load to which the supply has been connected has dropped below a threshold level.

This threshold level can be much lower than the normal current to the load. When it is, it can be difficult to detect when this threshold level has been reached.

One approach has been to measure the voltage drop across a sense resistor in series with the load. When the desired threshold level is much smaller than the normal operating current in the system, however, noise and offset errors in the system can make detection of the threshold level imprecise or can cause it to fail completely. This problem can be reduced by increasing the value of the sense resistor. However, such an increase can also increase power losses at normal operating current, which may be undesirable.

### SUMMARY

A threshold detection circuit may sense when current between a power supply and a load reaches a current threshold level. The threshold detection circuit may include a transistor in series with the load; a feedback circuit that causes the voltage drop across the transistor to be constant while the transistor is conducting current between the power supply and the load; a constant current source that delivers a constant current into the load; and a comparator that indicates when the voltage drop across the transistor falls below a voltage threshold level.

These, as well as other components, steps, features, objects, benefits, and advantages, will now become clear from a review of the following detailed description of illustrative embodiments, the accompanying drawings, and the claims.

### BRIEF DESCRIPTION OF DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1 illustrates an example of a power supply, a load, and a threshold detection circuit that can accurately detect when current between the power supply and the load reaches a threshold.

### DETAILED DESCRIPTION OF ILLUSTRATIVE EMBODIMENTS

Illustrative embodiments are now described. Other embodiments may be used in addition or instead. Details that may be apparent or unnecessary may be omitted to save space or for a more effective presentation. Some embodiments may be practiced with additional components or steps and/or without all of the components or steps that are described.

A threshold detection circuit can accurately detect when current between a power supply and a load reaches a very low threshold level, such as at or below 100, 50, 25, 10, 5, or 1 μA.

The threshold detection circuit may include a transistor, such as a MOSFET or BJT. The transistor may be in series between the power supply and the load and may function as a current sensing element.

The transistor may be driven by a feedback circuit that causes a small, constant voltage drop (Vdrop) across the transistor.

A constant current source may be connected to the load in parallel with the transistor and may supply a constant current to the load. The level of this constant current may be the same as the threshold level of the current to be detected by the threshold detection circuit. The constant current source may be configured such that it continues to deliver the constant current into the load, even when the voltage across the transistor falls below Vdrop.

At normal load current levels, the transistor may carry nearly all of the load current, while the constant current source may only contribute a small additional amount of current to the load, equal to the desired threshold current value. As the load current drops, the feedback circuit may adjust the transistor's drive to keep Vdrop constant.

Eventually, the load current may approach the constant current source current. In turn, this may cause the feedback circuit to turn the transistor completely off. At this point, the voltage across the transistor Vdrop may decrease abruptly while the current source supplies current to the load. This sharp decrease may be sensed with a comparator or other type of sensing circuit.

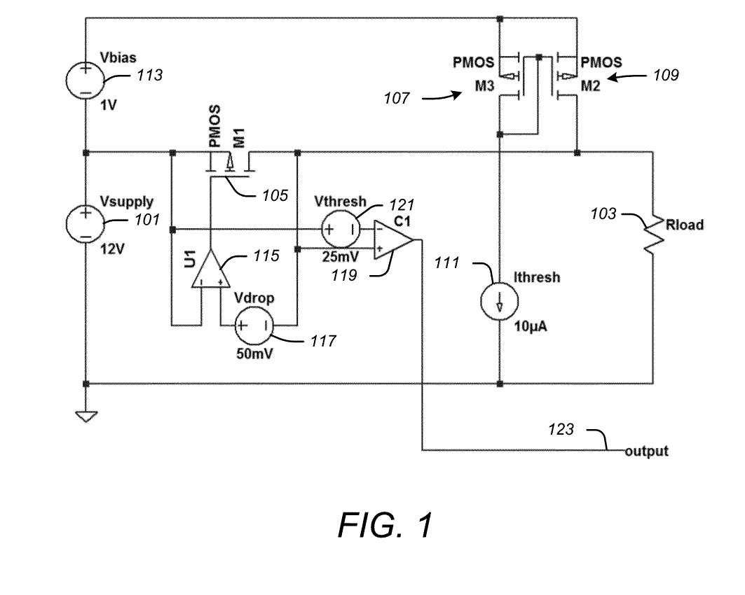

FIG. 1 illustrates an example of a power supply 101, a load 103, and a threshold detection circuit that can accurately detect when current between the power supply 101 and the load 103 reaches a threshold level.

The power supply 101 may be of any type. For example, the power supply may be a fixed DC voltage (e.g., 12 volts) power supply, a battery, or a variable voltage power supply.

The load 103 may be of any type. For example, the load 103 may be a variable load, such as an electronic device with a low power mode, or a PoE-powered access point.

The threshold detection circuit may include a transistor 105 connected in series between the power supply 101 and the load 103. The transistor may be of any type, such as a MOSFET or BJT. The transistor 105 may carry the majority of the current between the power supply 101 and the load 103.

The threshold detection circuit may include a constant current source. The constant current source may be of any type. For example, the constant current source may include MOSFETs 107 and 109 with their gates connected together and their sources connected together, as shown in FIG. 1. Other types of transistors may be used instead with appropriate circuit modifications.

The constant current source may include a reference current generator 111 that generates a reference current substantially equal to the desired threshold current (e.g., 10 μA). The reference current generator 111 may be a resistor or an electronic reference circuit.

The threshold detection circuit may include a bias voltage source 113. The bias voltage source may provide a bias voltage in an amount that keeps MOSFETs 107 and 109 operating as a current source, even when the voltage across the transistor 105 drops to a very low value.

The threshold detection circuit may include a differential amplifier 115. The threshold detection circuit may include an offset voltage source 117 connected in series with an input to the differential amplifier 115. The offset voltage source 117 may generate an offset voltage that cooperates with the amplifier 115 to cause the voltage Vdrop across the transistor 105 to be constant, notwithstanding changing in the load current. The amount of the offset voltage may be 50 mV or any value that keeps power dissipation in transistor 105 at a reasonable value.

The threshold detection circuit may include a comparator 119 and a threshold voltage generator 121. The threshold voltage generator 121 may generate a constant voltage that is below the constant voltage maintained across the transistor 105. In conjunction with the threshold voltage generator 121, the comparator 119 may detect an abrupt decrease in the voltage across the transistor 105 and provide an output 123 indicating when the current threshold has been crossed.

Under normal load conditions (e.g., 10 A), the output of the comparator 119 may be low. When load current drops below 10 uA, the output of the comparator 119 may go high. Thus, the threshold detection circuit may sense the load current relative to the level of the current from the constant current generator 111 very accurately, even when the normal load current is much higher than the level of the current from the constant current generator 111, such as 10,000, 100,000, 1,000,000, or even 10,000,000 times higher.

The threshold detection circuit may be used in a negative rail of a power supply, rather than in the positive rail as shown in FIG. 1. This may be done, for example, by using an N-channel MOSFET as the transistor 105.

The threshold detection circuit may instead be used in the positive rail of a power supply with an N-channel MOSFET by using a separate supply voltage or a charge pump that biases the gate drive and the current source.

The threshold detection circuit can also be built with bipolar NPN or PNP transistors.

The components, steps, features, objects, benefits, and advantages that have been discussed are merely illustrative. None of them, nor the discussions relating to them, are intended to limit the scope of protection in any way. Numerous other embodiments are also contemplated. These include embodiments that have fewer, additional, and/or different components, steps, features, objects, benefits, and/or advantages. These also include embodiments in which the components and/or steps are arranged and/or ordered differently.

Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

All articles, patents, patent applications, and other publications that have been cited in this disclosure are incorporated herein by reference.

The phrase “means for” when used in a claim is intended to and should be interpreted to embrace the corresponding structures and materials that have been described and their equivalents. Similarly, the phrase “step for” when used in a claim is intended to and should be interpreted to embrace the corresponding acts that have been described and their equivalents. The absence of these phrases from a claim means that the claim is not intended to and should not be interpreted to be limited to these corresponding structures, materials, or acts, or to their equivalents.

The scope of protection is limited solely by the claims that now follow. That scope is intended and should be interpreted to be as broad as is consistent with the ordinary meaning of the language that is used in the claims when interpreted in light of this specification and the prosecution history that follows, except where specific meanings have been set forth, and to encompass all structural and functional equivalents.

Relational terms such as “first” and “second” and the like may be used solely to distinguish one entity or action from another, without necessarily requiring or implying any actual relationship or order between them. The terms “comprises,” “comprising,” and any other variation thereof when used in connection with a list of elements in the specification or claims are intended to indicate that the list is not exclusive and that other elements may be included. Similarly, an element proceeded by an “a” or an “an” does not, without further constraints, preclude the existence of additional elements of the identical type.

None of the claims are intended to embrace subject matter that fails to satisfy the requirement of Sections 101, 102, or 103 of the Patent Act, nor should they be interpreted in such a way. Any unintended coverage of such subject matter is hereby disclaimed. Except as just stated in this paragraph, nothing that has been stated or illustrated is intended or should be interpreted to cause a dedication of any component, step, feature, object, benefit, advantage, or equivalent to the public, regardless of whether it is or is not recited in the claims.

The abstract is provided to help the reader quickly ascertain the nature of the technical disclosure. It is submitted with the understanding that it will not be used to interpret or limit the scope or meaning of the claims. In addition, various features in the foregoing detailed description are grouped together in various embodiments to streamline the disclosure. This method of disclosure should not be interpreted as requiring claimed embodiments to require more features than are expressly recited in each claim. Rather, as the following claims reflect, inventive subject matter lies in less than all features of a single disclosed embodiment. Thus, the following claims are hereby incorporated into the detailed description, with each claim standing on its own as separately claimed subject matter.

The invention claimed is:

1. A threshold detection circuit for sensing when current between a power supply and a load reaches a current threshold level comprising:
a transistor in series with the load;
a feedback circuit that causes the voltage drop across the transistor to be constant while the transistor is conducting current between the power supply and the load;
a constant current source that delivers a constant current into the load; and
a comparator that indicates when the voltage drop across the transistor falls below a voltage threshold level.

2. The threshold detection circuit of claim 1 wherein the constant current source is in parallel with the transistor.

3. The threshold detection circuit of claim 1 further comprising a constant bias voltage source connected to the constant current source.

4. The threshold detection circuit of claim 1 wherein the constant current source includes a current mirror circuit.

5. The threshold detection circuit of claim 1 wherein the constant current source includes a resistor.

6. The threshold detection circuit of claim 5 wherein the constant current source does not include a transistor.

7. The threshold detection circuit of claim 1 wherein the transistor is a MOSFET.

8. The threshold detection circuit of claim 7 wherein the MOSFET is a P-MOSFET.

9. The threshold detection circuit of claim 7 wherein the MOSFET is an N-MOSFET.

10. The threshold detection circuit of claim 1 wherein the transistor is a BJT.

11. The threshold detection circuit of claim 10 wherein the BJT is an NPN transistor.

12. The threshold detection circuit of claim 10 wherein the BJT is a PNP transistor.

13. The threshold detection circuit of claim 1 wherein the feedback circuit includes an amplifier.

14. The threshold detection circuit of claim 13 wherein the feedback circuit includes an offset voltage source.

15. The threshold detection circuit of claim 1 further comprising a threshold voltage generator connected to the comparator.

16. The threshold detection circuit of claim 1 further comprising a reference current generator connected to the constant current source.

17. The threshold detection circuit of claim 1 wherein the current threshold level is at or below 100 μA.

18. The threshold detection circuit of claim 1 wherein the current between the power supply and the load is usually within a range and wherein the current threshold level is substantially below that range.

19. The threshold detection circuit of claim 18 wherein the current threshold level is at least 10,000 times below that range.

20. The threshold detection circuit of claim 18 wherein the current threshold level is at least 100,000 times below that range.
